(19) United States
(12) Patent Application Publication
(10) Pub. No.: US 2026/0121089 A1
(43) Pub. Date: Apr. 30, 2026

(54) POWER DISTRIBUTION USING ELECTROLYTE FLUID

(71) Applicant: Microsoft Technology Licensing, LLC, Redmond, WA (US)

(72) Inventors: Sean Michael JAMES, Olympia, WA (US); Jonathan Brooks HORNER, Everett, WA (US); Bradley KELL, Encinitas, CA (US); David RIDLEY, Shoreline, WA (US); Zhenguo YANG, Bellevue, WA (US); Richard Otto WINTER, Gwynedd Valley, PA (US)

(21) Appl. No.: 18/928,913

(22) Filed: Oct. 28, 2024

(51) Int. Cl. H01M 8/04276; H01M 8/04007; H01M 8/04537; H01M 8/04746; H01M 8/18; H05K 7/20

(52) U.S. Cl. CPC H01M 8/04276; H01M 8/04074; H01M 8/04604; H01M 8/04746; H01M 8/188; H01M 2250/10; H05K 7/20763

(57) ABSTRACT

Power distribution using electrolyte fluid is disclosed. Electrolyte fluid is charged at a charging stack using electricity from an electrical power source. The charged electrolyte fluid is flowed through an electrolyte loop to a load stack. At the load stack, electrochemical energy in the charged electrolyte fluid is used to supply electricity to power an electrical load.

### BACKGROUND

Electrochemical energy can be stored in electrolyte fluids. To charge the electrolyte fluids, an electrical current is applied to an electrochemical cell that includes anolyte fluid flowing near an anode separated by a membrane from catholyte fluid flowing near a cathode. When the electrical current is applied to the electrochemical cell, the anolyte fluid flowing near the anode reduces to produce free ions that pass through the membrane. On the other side of the membrane, oxidation of the catholyte fluid occurs. This charging process increases the ionic differential between the catholyte and anolyte resulting in a higher state of charge. To discharge the electrolyte fluids, the catholyte fluid flowing near the cathode reduces to produce free ions that pass through the membrane in the opposite direction. On the other side of the membrane, oxidation of the anolyte fluid occurs, resulting in an electrical current that can be used to supply electricity to power an electrical load.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Power distribution using electrolyte fluid is disclosed herein. Electrolyte fluid is charged at a charging stack using electricity from an electrical power source. The charged electrolyte fluid is flowed through an electrolyte loop to a load stack. At the load stack, electrochemical energy in the charged electrolyte fluid is used to supply electricity to power an electrical load. In embodiments, a first heat exchanger transfers heat generated by the electrical load to the electrolyte fluid, and the heated electrolyte fluid moves to an electrolyte chiller where it is cooled.

Further features and advantages of the embodiments, as well as the structure and operation of various embodiments, are described in detail below with reference to the accompanying drawings. It is noted that the claimed subject matter is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form a part of the specification, illustrate embodiments of the present application and, together with the description, further serve to explain the principles of the embodiments and to enable a person skilled in the pertinent art to make and use the embodiments.

FIG. 1 shows a block diagram of an example system for power distribution using electrolyte fluid, in accordance with an embodiment.

FIG. 2 shows a block diagram of an example system for power distribution and load cooling using electrolyte fluid, in accordance with an embodiment.

FIG. 3 shows a block diagram of an example system for charging electrolyte fluid using a charging stack, in accordance with an embodiment.

FIG. 4 shows a block diagram of an example system for powering electrical loads using a load stack, in accordance with an embodiment.

FIG. 5 shows a block diagram of an example system for heat exchange using electrolyte fluid, in accordance with an embodiment.

FIG. 6 depicts a flowchart of a process for power distribution using electrolyte fluid, in accordance with an embodiment.

FIG. 7 depicts a flowchart of a process for controlling a flow rate of electrolyte fluid into a load stack, in accordance with an embodiment.

FIG. 8 depicts a flowchart of a process for charging first electrolyte fluid in an electrolyte loop using second electrolyte fluid stored in an electrolyte tank at a higher state of charge, in accordance with an embodiment.

FIG. 9 depicts a flowchart of a process for heat transfer using electrolyte fluid, in accordance with an embodiment.

FIG. 10 depicts a flowchart of a process for isolating an electrolyte fluid leak, in accordance with an embodiment.

FIG. 11 shows a block diagram of an example computer system in which embodiments may be implemented.

The subject matter of the present application will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION

### I. Introduction

The following detailed description discloses numerous example embodiments. The scope of the present patent application is not limited to the disclosed embodiments, but also encompasses combinations of the disclosed embodiments, as well as modifications to the disclosed embodiments. It is noted that any section/subsection headings provided herein are not intended to be limiting. Embodiments are described throughout this document, and any type of embodiment may be included under any section/subsection. Furthermore, embodiments disclosed in any section/subsection may be combined with any other embodiments described in the same section/subsection and/or a different section/subsection in any manner.

As used herein, the term “electrolyte” refers to a fluid that conducts electricity by allowing free ions to move a first electrode and a second electrode.

As used herein, the term “anode” refers to an electrode in contact with the anolyte fluid. In embodiments, the anode is connected to the negative terminal.

As used herein, the term “cathode” refers to an electrode in contact with the catholyte fluid. In embodiments, the cathode is connected to the positive terminal.

As used herein, the term “anolyte” refers to electrolyte fluid that comes in contact with the anode.

As used herein, the term “catholyte” refers to electrolyte fluid that comes in contact with the cathode.

As used herein, the term “electrolyte loop” refers to any object capable of transporting electrolyte fluid from a first location to a second location and back to the first location.

As used herein, the term “anolyte loop” refers to any object capable of transporting anolyte fluid from a first location to a second location and back to the first location.

As used herein, the term “catholyte loop” refers to any object capable of transporting catholyte fluid from a first location to a second location and back to the first location.

As used herein, the term “stack” refers to a series of one or more electrochemical cells stacked together, each electrochemical cell comprising at least an anode, a cathode, and a membrane separating the anode and the cathode.

As used herein, the term “pump” refers to any device capable of moving fluid using suction or pressure.

### II. Example Embodiments

A data center is a facility such as a building, group of buildings, or dedicated space within a building used to house computer systems and associated components, such as telecommunications and storage systems. Data center power distribution systems manage the delivery of electrical power to various critical components within the facility, ensuring reliable and efficient operation. Conventionally, the power distribution system converts high-voltage power from the utility to a lower voltage using step-down transformers. This power is then routed through uninterruptible power supplies (UPS) that provide backup power and conditioning to protect against fluctuations and outages. From the UPS, the power is distributed via power distribution units (PDUs) to server racks, and/or networking equipment within the data center. Conventional power distribution systems face many issues, such as, but not limited to, power stranding, power fragmentation, load balancing, and power conversions.

Power distribution using electrolyte fluid mitigates many issues related to conventional power distribution systems. Power distribution using electrolyte fluid starts by converting electricity into electrochemical energy at a charging stack. For instance, electricity is applied at the charging stack to cause free ions (e.g., free protons, free electrons, etc.) to flow from a catholyte fluid to an anolyte fluid through a membrane separating the catholyte fluid and the anolyte fluid. This process charges the anolyte fluid and catholyte fluid by increasing the ionic differential between the anolyte fluid and the catholyte fluid. The charged anolyte fluid and catholyte fluid are flowed through an anolyte loop and a catholyte loop, respectively, to a load stack. At the load stack, the ionic differential between the anolyte fluid and the catholyte fluid cause free electrons to flow from the anolyte fluid to the catholyte fluid through a membrane separating the catholyte fluid and the anolyte fluid. This discharging process generates a direct current (DC) electricity to power an electrical load.

Various benefits are realized through the use of electrolyte fluid for power distribution. For instance, converting electricity into electrochemical energy at a charging stack and converting the electrochemical energy back to electricity at a separate load stack enables the electrolyte fluid to act as energy storage and decouples the electricity source from the electrical loads. This prevents electrical perturbances (e.g., outages, spikes, etc.) occurring at the electricity source from reaching the electrical loads, thereby providing uninterrupted and conditioned power to the electrical loads. Furthermore, the decoupling of the charging stack and the load stack allow for different voltages at each location, eliminating the need for additional conversion devices (e.g., step-down transformers). For example, high voltage electrical power (e.g., 480 VAC, 120 VAC, etc.) can be provided to power electronics in the charging stack to charge the electrolyte fluid while low voltage electrical power (e.g., 12 VDC, 24 VDC, etc.) may be extracted at the load stack and provided directly to an electrical load (e.g., server rack, etc.). This eliminates the need for 480 VAC to 415 VAC transformers and 415 VAC to 12 VDC power supplies typically found in conventional data center power distribution systems. Additionally, because electrolyte fluid is not at risk of short circuiting hazardously, protection is only needed at the input to the data center power distribution system and at the electrical loads, thus eliminating the need for several layers of branching circuits and circuit protection typically found in conventional data center power distribution systems.

In addition to using electrolyte fluid to power a data center, the electrolyte fluid can also be used for liquid cooling. For instance, as electrolyte fluid flows through the data center, the electrolyte fluid is passed through a first heat exchanger at an electrical load (e.g., server rack, etc.) to transfer heat from the electrical load to the electrolyte fluid. The heated electrolyte fluid is then flowed through the electrolyte loop to a second heat exchanger where heat is transferred from the electrolyte fluid to a cooling fluid. In embodiments, the heated cooling fluid is used at a third heat exchanger to warm another fluid (e.g., air, water, etc.) to provide warm water and/or heat to other portions of the building and/or other buildings.

According to embodiments, additional electrolyte fluid is stored in an electrolyte storage tank at different (e.g., higher, lower, etc.) state (e.g., temperature, SOC, etc.) than electrolyte fluid flowing through the electrolyte loop. For instance, additional electrolyte fluid is stored in an electrolyte storage tank at a higher state of charge (SOC) (e.g., 90% SOC, 100% SOC, etc.) to provide protection from power shortage and/or outages. For instance, additional anolyte fluid and catholyte fluid are stored in an anolyte fluid storage tank and a catholyte fluid storage tank, respectively, at the higher SOC. In embodiments, when power provided by an electrical power source is insufficient to charge the electrolyte fluid in the electrolyte loop, the electrolyte fluid stored in the electrolyte storage tank at the higher SOC is pumped into the electrolyte loop to increase the SOC of the electrolyte fluid flowing through the electrolyte loop. For instance, the anolyte fluid and/or catholyte fluid stored in the anolyte fluid storage tank and/or the catholyte fluid storage tank are pumped into the anolyte loop and catholyte loop, respectively, when there is insufficient electrical power (e.g., due to an electrical outage, insufficient electrical supply, component failure, etc.).

These and further embodiments enable the functionality described above and additional functionality. Such embodiments are described in further detail as follows.

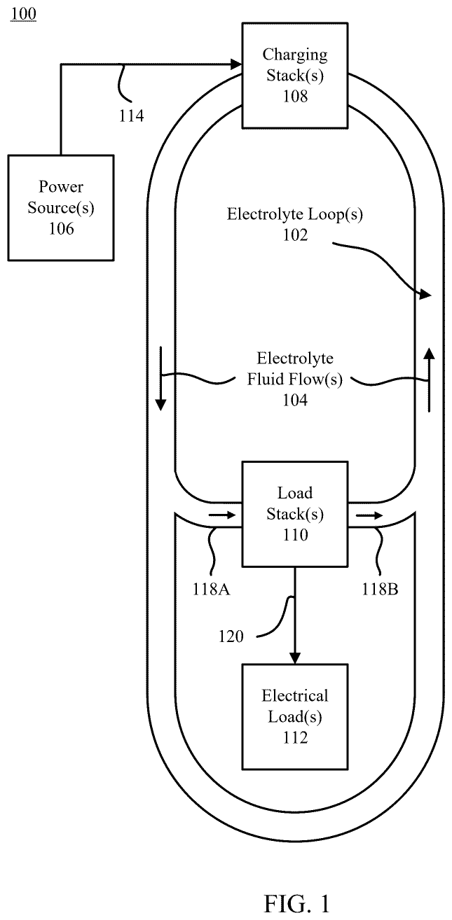

For example, FIG. 1 shows a block diagram of an example system 100 for power distribution using electrolyte fluid, in accordance with an embodiment. As shown in FIG. 1, system 100 includes one or more electrolyte loops 102, one or more electrolyte fluid flows 104, one or more power sources 106, one or more charging stacks 108, one or more load stacks 110, and one or more electrical loads 112. System 100 is described in further detail as follows.

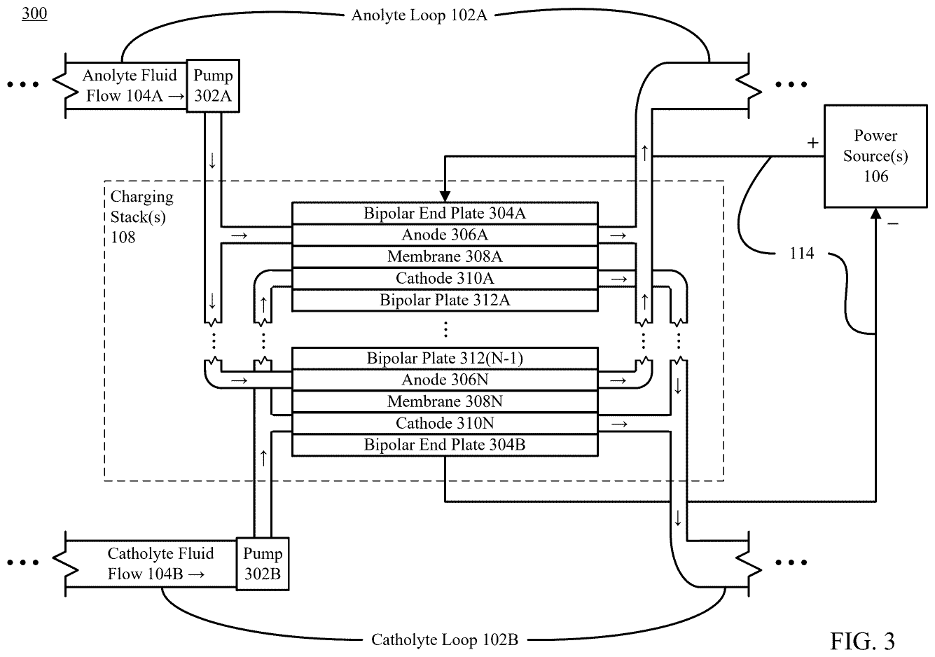

Electrolyte loop(s) 102 comprise any structure (e.g., tube, pipe, tank, trough, trench, groove, vessel, etc.) capable of transporting electrolyte fluid from charging stack(s) 108 to load stack(s) 110, and then from load stack(s) 110 back to charging stack(s) 108. In embodiments, electrolyte loop(s) 102 includes an anolyte loop 102A and a catholyte loop 102B, which will be discussed in greater detail in conjunction with FIG. 3 below. In embodiments, electrolyte loop(s) 102, such as anolyte loop 102A and/or catholyte loop 102B, are made of a material and/or combination of materials (e.g., metal, plastic, glass, ceramic, rubber, etc.) appropriate for transporting the electrolyte, such as anolyte and/or catholyte, respectively.

Electrolyte fluid flow(s) 104 comprises a movement of electrolyte fluid flowing through electrolyte loop(s) 102. In embodiments, electrolyte fluid flow(s) 104 includes an anolyte fluid flow 104A and a catholyte fluid flow 104B, which will be discussed in greater detail in conjunction with FIG. 3 below. In embodiments, the flow rate(s) of electrolyte fluid flow(s) 104 are controlled using one or more pumps based on information from one or more sensors connected to electrolyte loop(s) 102. In embodiments, additives designed to react with ambient air outside of the electrolyte loop(s) 102 are added to electrolyte fluid flow(s) 104 in order cause a leak of electrolyte fluid flow(s) 104 to self-repair.

Power source(s) 106 comprise one or more electrical power sources that supply electrical power to a site (e.g., building, data center, etc.). In embodiments, power source(s) 106 include, but are not limited to, an electrical power grid, a solar power source (e.g., photovoltaic cells, etc.), a wind power source (e.g., wind turbine generator, etc.), a hydroelectric power source (e.g., water turbine, etc.), a geothermal energy source (e.g., steam turbine, etc.), an ocean energy system, an onsite backup power source (e.g., backup generator, etc.), an energy storage device (e.g., battery, pumped hydroelectric reservoir, compressed air energy storage, gravity battery, thermal energy storage, flywheel energy storage, etc.), a nuclear power source, a fuel cell, and/or the like. In embodiments, power source(s) 106 are implemented using large power conversion systems (PCS), solid state transformers (SST), a large array of small devices, and/or the like. In embodiments, power source(s) 106 supplies an electrical current 114 to load stack(s) 108. In embodiments electrical current 114 comprises electrical current of various voltages (12 VDC, 24 VDC, 120 VAC, 240 VAC, 460 VAC), of various phases (e.g., single-phase, double-phase, three-phase, etc.), and/or of various frequencies (e.g., 50 Hz, 60 Hz, etc.). In embodiments, electrical current 114 is converted from AC to DC prior to or upon arriving at charging stack(s) 108.

Charging stack(s) 108 comprise one or more stacks of electrochemical cells stacked together. In embodiments, the electrochemical cells comprise at least an anode, a cathode, and a membrane separating the anode and the cathode. In embodiments, the electrochemical cells in charging stack(s) 108 are separated by one or more bipolar plates. In embodiments, the number of electrochemical cells in charging stack(s) 108 depends on characteristics (e.g., voltage, amperage, frequency, etc.) of electrical current 114 supplying electrical power to charging stack(s) 108. In embodiments, the number of electrochemical cells in any charging stack 108 may be the same or different from the number of electrochemical cells in other charging stack(s) 108.

Load stack(s) 110 comprise one or more stacks of electrochemical cells stacked together. In embodiments, the electrochemical cells comprise at least an anode, a cathode, and a membrane separating the anode and the cathode. In embodiments, the electrochemical cells in charging stack(s) 108 are separated by one or more bipolar plates. In embodiments, the number of electrochemical cells in load stack(s) 110 depend on characteristics (e.g., voltage, amperage, etc.) of electrical current 120 supplying electrical power to electrical load(s) 112. In embodiments, the characteristics (e.g., voltage, amperage, etc.) of electrical current 120 supplying electrical power to electrical load(s) 112 differs from the characteristics (e.g., voltage, amperage, frequency, etc.) of electrical current 114 supplying electrical power to charging stack(s) 108. In embodiments, the number of electrochemical cells in a particular load stack 110 may be the same or different from the number of electrochemical cells in other load stack(s) 110. In embodiments, load stack(s) 110 are connected to electrical load(s) 112 via one or more circuit breakers and/or other circuit protector (not depicted). In embodiments, load stack(s) 110 are located at various locations throughout system(s) 100 and/or 200, such as, but not limited to, at an infrastructure level, within a rack, within individual blades in a rack, at a microchip level, and/or any combination thereof.

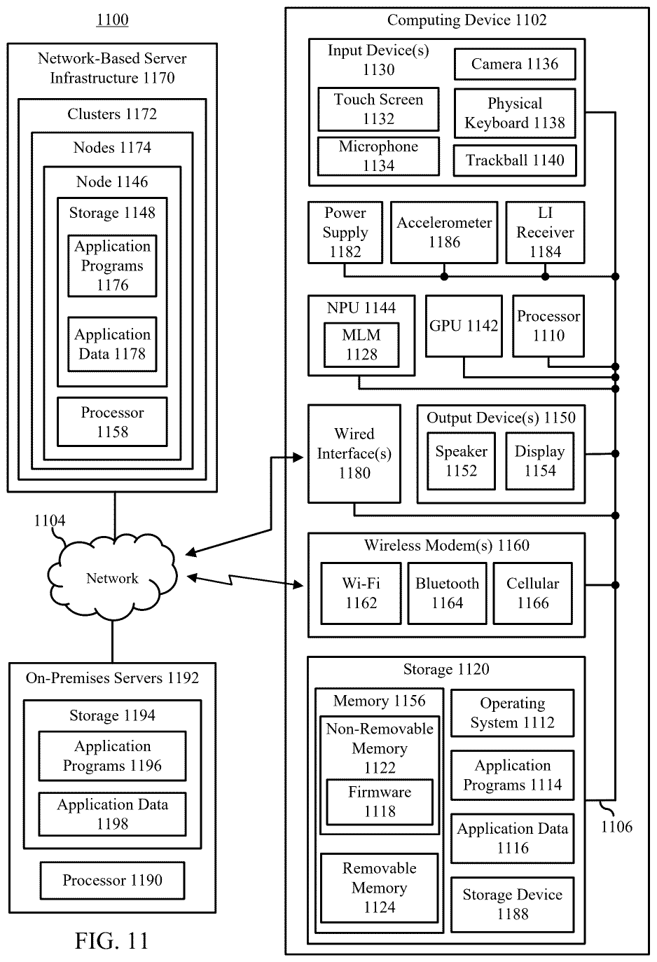

Electrical load(s) 112 comprise any device that consumes electricity, such as, but not limited to, a server, a server rack, a central processing unit, a graphics processing unit, a Tensor processing unit, a neural processing unit, a storage cluster, a network component, a DC-to-DC converter; a DC-to-AC inverter, an air handler, a chiller, a fan, a pump, a compressor, lighting, and/or the like. In embodiments, the characteristics (e.g., voltage, amperage, etc.) of electrical current 120 supplying electrical power to electrical load(s) 112 depend on the electrical requirements of electrical load(s) 112. In embodiments, electrical load(s) 112 includes one or more circuit breakers and/or other circuit protector (not depicted). Various example implementations of electrical load(s) 112 are described below in reference to FIG. 11 (e.g., computing device 1102, network 1104, network-based server infrastructure 1170, on-premises servers 1192, and/or components thereof).

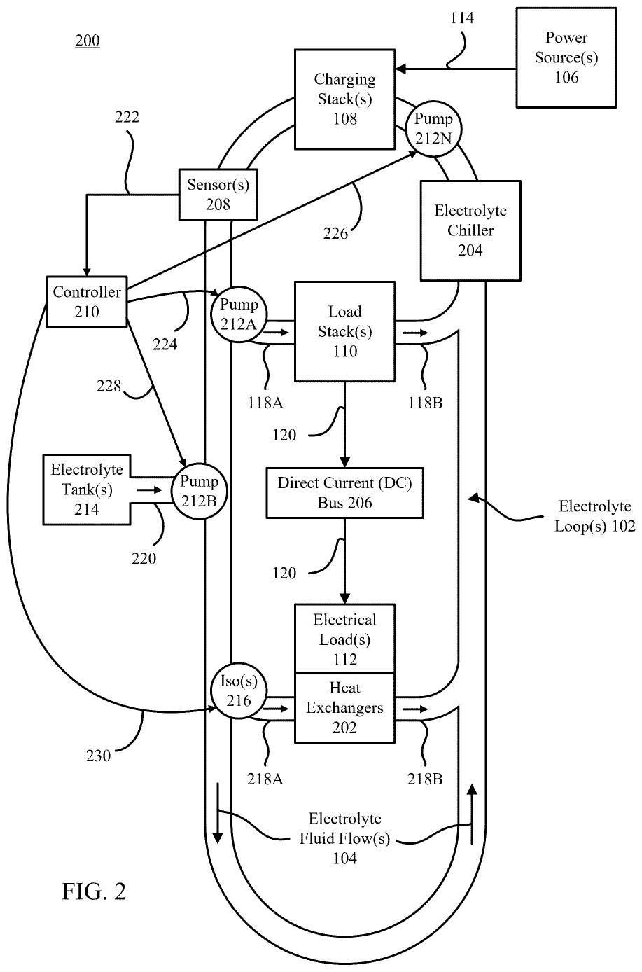

Embodiments described herein may operate in various ways to implement power distribution and heat transfer using electrolyte fluid. For instance, FIG. 2 depicts a block diagram of a system 200 for power distribution and heat transfer using electrolyte fluid, in accordance with an embodiment. As shown in FIG. 2, system 200 includes electrolyte loop(s) 102, electrolyte fluid flow(s) 104, power source(s) 106, charging stack(s) 108, load stack(s) 110, electrical load(s) 112, one or more heat exchangers 202, a heat exchanger 204, a DC bus 206, one or more sensors 208, a controller 210, one or more pumps 212A-212N, one or more electrolyte tanks 214, and one or more isolators 216. System 200 is described in further detail as follows.

Heat exchanger(s) 202 comprises any device capable of transferring heat from electrical load(s) 112 to electrolyte fluid flowing in electrolyte loop(s) 102. In embodiments, heat exchanger(s) 202 include, but are not limited to, shell-and-tube heat exchangers, plate heat exchangers, double-pipe heat exchangers, parallel-flow heat exchangers, counterflow heat exchangers, air-cooled heat exchangers, rear door heat exchangers, and/or the like.

Heat exchanger 204 comprises any device capable of removing heat from electrolyte fluid flowing in electrolyte loop(s) 102. In embodiments, heat exchanger 204 includes, but is not limited to, a shell-and-tube heat exchanger, a plate heat exchanger, a double-pipe heat exchanger, a parallel-flow heat exchanger, a counterflow heat exchanger, an air-cooled heat exchanger, an air-cooled radiator, a fluid chiller, a rear door heat exchanger, and/or the like.

DC bus 206 comprises electrical components for distributing direct current power to electrical load(s) 112. In embodiments, DC bus 206 comprises conductive pathways, such as, but not limited to, copper and/or aluminum bars and/or cables, that connect load stack(s) 110 to electrical load(s) 112. In embodiments, DC bus 206 supplies DC power to a DC-to-AC inverter to convert DC power to AC power in order to power electrical load(s) 112 that require AC power. In embodiments, DC bus 206 are connected to load stack(s) 110 and/or electrical load(s) 112 via one or more circuit breakers and/or other circuit protector (not depicted). In embodiments, the ratio of load stack(s) 110 to electrical load(s) 112 are determined based on a desired amount of redundancy or failover. For instance, a ratio of 1:1 or less provides no redundancy against failure of load stack(s) 110, while any ratio above 1:1 provides some redundancy.

Sensor(s) 208 are configured to measure the state and/or configuration of system 100, system 200, and/or components thereof. In embodiments, sensor(s) 208 comprise, but are not limited to, SOC sensors to measure the SOC of the electrolyte fluid(s), temperature sensors to measure the temperature of the electrolyte fluid(s), flow sensors to measure the flow rate of electrolyte fluid flow(s) 104 in electrolyte loop(s) 102, pressure sensors to measure the pressure of the electrolyte fluid(s), fluid level sensors to measure the level of electrolyte fluid(s) in electrolyte loop(s) 102 and/or electrolyte tank(s) 214, vibration sensors, electrical conductivity sensors, thermal conductivity sensors, pH sensors, viscosity sensors, specific gravity sensors, vapor pressure sensors, bubble sensors to detect the presence of bubbles in the electrolyte fluid(s), spectral/opacity sensors to measure light absorption and/or refraction, sensors to measure constituents of electrolyte fluid(s) or gas(es), voltage-to-ground sensors, isolation-from-ground sensors, average oxidation state (AOS) sensors to measure the concentration of the electrolyte fluid(s) at each its valance states, leak sensors to measure gas and/or liquid leaks, open circuit voltage (OCV) sensor to measure an amount of energy stored in the electrolyte fluid(s), non-OCV sensors to measure non-OCV of charging stack(s) 108 and/or load stack(s) 110, and/or a reference cell used to measure the state of health of the electrolyte fluid(s). In embodiments, sensor(s) 208 provides system state information 222 to controller 210.

Controller 210 comprises one or more devices configured to receive system state information 222 from sensor(s) 208, and provide signals 224-230 to control the operation of pump(s) 212A-212N, and/or isolator(s) 216. In embodiments, controller 210 is implemented as a centralized controller and/or a plurality of distributed controllers that operate independently and/or in cooperation with the centralized controller and/or with other distributed controllers. In embodiments, controller 210 is implemented as a centralized controller communicatively coupled to a plurality of I/O (input/output) modules. For instance, controller 210 provides signals 224-228 to pump(s) 212A-212N, respectively, to control one or more of: the flow rate, the pressure, the concentration, and/or SOC of the electrolyte fluid(s) at various locations within of system(s) 100 and/or 200. In embodiments, controller 210 maintains the electrolyte fluid(s) at a predetermined SOC (e.g., 50% SOC, 60% SOC, etc.) by controlling various parameters, such as, but not limited to, the flow rate of the electrolyte fluid(s) through charging stack(s) 108, the amount of electrical voltage, current and/or power supplied by power source(s) 106, the operational status of charging stack(s) 108, and/or the like. In embodiments, controller 210 adjusts the pressure of electrolyte fluid flow(s) 104 at various locations in system(s) 100 and/or 200, in order to improve the recharging efficiency, the discharging efficiency, the state of health of the system, and/or the heat transfer rate. In embodiments, responsive to a detected leak, controller 210 provides signal(s) 230 to isolator(s) 216 to isolate one or more components of system(s) 100 and/or 200 from the rest of system(s) 100 and/or 200. In embodiments, responsive to a detected leak, controller 210 provides signal(s) 224-228 to pump(s) 212A-212N to alter pump operations of pump(s) 212A-212N. In embodiments, controller 210 detects a deterioration of the electrolyte fluid(s) based on the AOS and/or other parameters measured through sensor(s) 208, and performs a remedial action, such as, but not limited to, replacing at least a portion of the catholyte fluid in catholyte loop 102B with replacement catholyte fluid, introducing fructose and/or other additive to the catholyte, and/or the like. In embodiments, controller 210 maintains an AOS balance by matching the volume between the anolyte fluid in anolyte loop 102A and the catholyte fluid in catholyte loop 102B by, for example, but not limited to, maintaining the anolyte fluid and catholyte fluid at different pressure, and/or maintaining an overflow connecting the anolyte loop 102A and catholyte loop 102B.

Pump(s) 212A-212N comprise one or more devices configured to move electrolyte fluid(s) through system(s) 100 and/or 200 using suction and/or pressure. In embodiments, pump(s) 212A-212N operate using, for example, but not limited to, rotating impellers, pistons, diaphragms, vanes, gears, screws, peristaltic forces, electrostatic forces, ionic forces, and/or other motive forces. In embodiments, pump(s) 212A-212B are positioned at various locations in system(s) 100 and/or 200, including, but not limited to, along electrolyte loop(s) 102, at one or more inlets (e.g., 118A, 218A, etc.) connected to electrolyte loop(s) 102, at one or more outlets (e.g., 118B, 218B, 220, etc.) connected to electrolyte loop(s) 102, inside one or more of charging stack(s) 108, load stack(s) 110, heat exchanger(s) 202, heat exchanger 204, and/or anywhere else in system(s) 100 and/or 200. In embodiments, pump(s) 212A-212N are controllable independently in order to vary the flow rate, pressure, temperature, and/or other aspect of electrolyte fluid flow(s) 104 at various locations within system(s) 100 and/or 200. In embodiments, a differential pressure between anolyte fluid and catholyte fluid is controlled by employing, for example, but not limited to, one or more dedicated pump(s) 212A-212N, alternate flow path (not depicted), and/or one or more valve(s) (not depicted).

Electrolyte tank(s) 214 comprise one or more tanks storing electrolyte fluid(s) at a different state (e.g., SOC, temperature, etc.) than electrolyte fluid in electrolyte loop(s) 102. For instance, an anolyte tank stores anolyte fluid at a different (e.g., higher, lower, etc.) SOC and/or a different (e.g., higher lower, etc.) temperature than the SOC and/or temperature of anolyte fluid in anolyte loop 102A, and a catholyte tank stores catholyte fluid at a different (e.g., higher, lower, etc.) SOC and/or a different (e.g., higher lower, etc.) temperature than the SOC and/or temperature of catholyte fluid in catholyte loop 102B. In embodiments, electrolyte tank(s) 214 can be partially and/or fully isolated from electrolyte loop(s) 102. In instances, electrolyte fluid(s) stored in electrolyte tank(s) 214 are pumped by pump(s) 212B into electrolyte loop(s) 102 to increase or decrease the SOC and/or the temperature of the electrolyte fluid(s) in electrolyte loop(s) 102. In embodiments, this may occur when power source(s) 106 and/or charging stack(s) 108 are unable to maintain a desired SOC of the electrolyte fluid(s) in one or more segments of system(s) 100 and/or 200 for various reasons, such as, but not limited to, insufficient power from power source(s) 106, higher than normal and/or expected load, a power outage associated with power source(s) 106, failure of charging stack(s) 108, isolation of charging stack(s) 108 due to a detected leak, and/or the like.

Isolator(s) 216 are configured to isolate portions of system(s) 100 and/or 200 from the remainder of system(s) 100 and/or 200. In embodiments, isolator(s) 216 include, but are not limited to, isolation valves, siphon break, inflatable balloon or bladder, freezing liquid, and/or the like. In embodiments, when maintenance is required and/or upon detecting a leak, controller 210 provides a signal 230 to isolator(s) 216 to cause isolator(s) 216 to isolate a portion of system(s) 100 and/or 200 from the remainder of system(s) 100 and/or 200 by, for example, but not limited to, actuating an isolation valve, and/or introducing a gas to cause to break a siphon in a siphon break. In embodiments, a technician manually actuates isolator(s) 126 by, for example, but not limited to, manually introducing a gas into isolator(s) 216 to isolate a portion of system(s) 100 and/or 200 from the remainder of system(s) 100 and/or 200. In embodiments, isolator(s) 216 are positioned at various locations in system(s) 100 and/or 200, including, but not limited to, along electrolyte loop(s) 102, at one or more inlets (e.g., 118A, 218A, etc.) connected to electrolyte loop(s) 102, at one or more outlets (e.g., 118B, 218B, 220, etc.) connected to electrolyte loop(s) 102, inside one or more of charging stack(s) 108, load stack(s) 110, heat exchanger(s) 202, heat exchanger 204, and/or anywhere else in system(s) 100 and/or 200.

Embodiments described herein may operate in various ways to charge electrolyte fluid using a charging stack. For instance, FIG. 3 depicts a block diagram of a system 300 for charging electrolyte fluid using a charging stack, in accordance with an embodiment. As shown in FIG. 3, system 300 includes an anolyte loop 102A, a catholyte loop 102B, an anolyte fluid flow 104A, a catholyte fluid flow 104B, power source(s) 106, charging stack(s) 108, a pump 302A, a pump 302B, one or more bipolar end plates 304A-304B, one or more anodes 306A-306N, one or more membranes 308A-308N, one or more cathodes 310A-310N, and one or more bipolar plates 312A-312N. System 300 is described in further detail as follows.

Anolyte loop 102A comprises any structure (e.g., tube, trough, trench, groove, etc.) capable of transporting anolyte fluid from charging stack(s) 108 to load stack(s) 110, and then from load stack(s) 110 back to charging stack(s) 108. In embodiments, anolyte loop 102A is made of a material and/or combination of materials (e.g., metal, plastic, glass, ceramic, rubber, etc.) appropriate for transporting the anolyte fluid, and may differ in material from catholyte loop 102B.

Catholyte loop 102B comprises any structure (e.g., tube, trough, trench, groove, etc.) capable of transporting catholyte fluid from charging stack(s) 108 to load stack(s) 110, and then from load stack(s) 110 back to charging stack(s) 108. In embodiments, catholyte loop 102B is made of a material and/or combination of materials (e.g., metal, plastic, glass, ceramic, rubber, etc.) appropriate for transporting the catholyte fluid, and may differ in material from anolyte loop 102A.

Anolyte fluid flow 104A comprises a movement of anolyte fluid flowing through anolyte loop 102A. In embodiments, anolyte fluid flow 104A moves through anolyte loop 102A at a same and/or different pressure, flow rate, temperature, concentration, SOC, and/or AOS than catholyte fluid flow 104B in catholyte loop 102B. In embodiments, an additive designed to react with ambient air outside of anolyte loop 102A is added to anolyte fluid flow 104A in order cause a leak of anolyte fluid flow 104A to self-repair.

Catholyte fluid flow 104B comprises a movement of catholyte fluid flowing through catholyte loop 102B. In embodiments, catholyte fluid flow 104B moves through catholyte loop 102B at a same and/or different pressure, temperature, concentration, SOC, and/or AOS than anolyte fluid flow 104A in anolyte loop 102A. In embodiments, an additive designed to react with ambient air outside of catholyte loop 102B is added to catholyte fluid flow(s) 104B in order cause a leak of catholyte fluid flow 104B to self-repair.

Pump(s) 302A-302B pump anolyte fluid and/or catholyte fluid from anolyte loop 102A and/or catholyte loop 102B across anode(s) 306A-306N and/or cathode(s) 310A-310N, respectively, and back into anolyte loop 102A and/or catholyte loop 102B.

Bipolar end plate(s) 304A-304B are connected to power source(s) 106 and are configured to conduct electrical current 114 from power source(s) 106 across the layers of charging stack(s) 108. In embodiments, electrical current 114 flows into bipolar end plate 304A, causing oxidation of the catholyte fluid flowing across cathode(s) 310A-310N which produces free ions that flow across membrane(s) 308A-308N, where reduction of the anolyte fluid flowing across anode(s) 306A-306N occurs. In embodiments, bipolar end plate(s) 304A-304B are made of a material and/or combination of materials (e.g., metal, metal alloys, carbon-based materials, conductive polymers, composites, etc.) appropriate for conducting electrical current across charging stack(s) 108. This process charges the electrolyte fluid(s) by increasing the ionic differential between the anolyte fluid and the catholyte fluid.

Anode(s) 306A-306N are configured to facilitate the reduction of the anolyte fluid in charging stack(s) 108. In embodiments, anode(s) 306A-306N are made of a material and/or combination of materials (e.g., metal, metal alloys, carbon-based materials, conductive polymers, organic material, composites, etc.) appropriate for reduction of the anolyte fluid, and may be made of the same and/or different material as cathode(s) 310A-310N. In embodiments, anode(s) 306A-306N are made of a porous material that enables anolyte fluid to flow through anode(s) 306A-306N, thereby increasing the contact area between anode(s) 306A-306N and the anolyte fluid.

Membrane(s) 308A-308N separate anolyte fluid flowing across anode(s) 306A-306N from catholyte fluid flowing across cathode(s) 310A-310N and enable selective ions to flow from the anolyte fluid to the catholyte fluid in charging stack(s) 108. In embodiments, membrane(s) 308A-308N are made of an ion-selective material or composites (e.g., polymers, microporous material, composite polymers, ceramic material, etc.) that allow the passage of specific ions while blocking others, such as, but not limited to, a proton-exchange membrane, a sulfonated tetrafluoroethylene based fluoropolymer-copolymer, and/or the like. In embodiments, membrane(s) 308A-308N are omitted from charging stack(s) 108.

Cathode(s) 310A-310N are configured to facilitate the oxidation of the catholyte fluid in charging stack(s) 108. In embodiments, cathode(s) 310A-310N are made of a material and/or combination of materials (e.g., metal, metal alloys, carbon-based materials, conductive polymers, organic material, composites, etc.) appropriate for oxidation of the catholyte fluid, and may be made of the same and/or different material as anode(s) 306A-306N. In embodiments, cathode(s) 310A-310N are made of a porous material that enables anolyte fluid to flow through cathode(s) 310A-310N, thereby increasing the contact area between cathode(s) 310A-310N and the catholyte fluid.

Bipolar plate(s) 312A-312(N-1) separate the electrochemical cells in charging stack(s) 108. In embodiments, bipolar plate(s) 312A-312(N-1) are made of a material and/or combination of materials (e.g., metal, metal alloys, carbon-based materials, conductive polymers, composites, etc.) appropriate for conducting electrical current between the electrochemical cells in charging stack(s) 108.

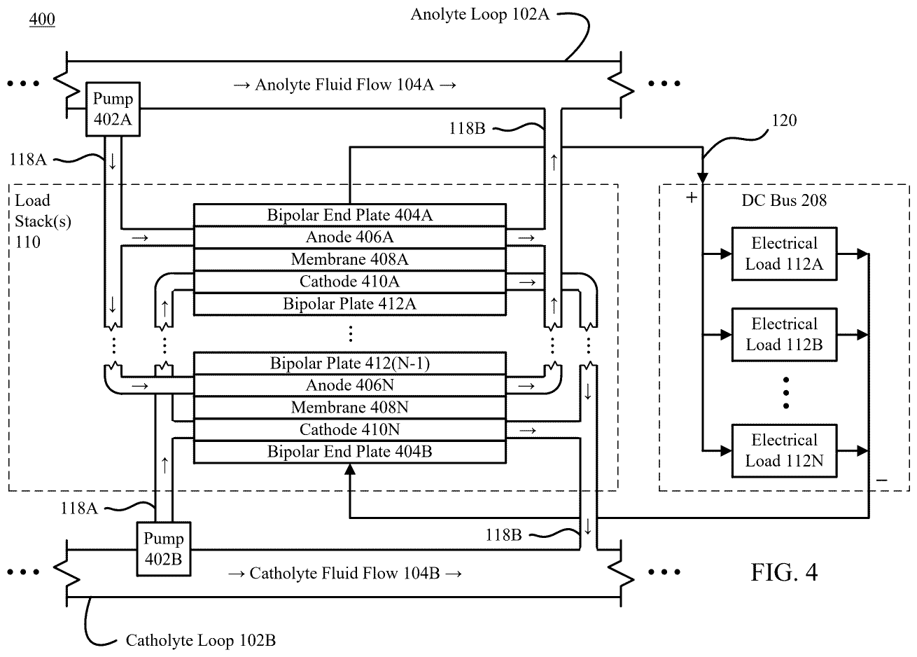

Embodiments described herein may operate in various ways to power electrical loads using a load stack. For instance, FIG. 4 depicts a block diagram of a system 400 for powering electrical loads using a load stack, in accordance with an embodiment. As shown in FIG. 4, system 400 includes anolyte loop 102A, catholyte loop 102B, anolyte fluid flow 104A, catholyte fluid flow 104B, load stack(s) 110, electrical load(s) 112A-112N, DC bus 206, a pump 402A, a pump 402B, one or more bipolar end plates 404A-404B, one or more anodes 406A-406N, one or more membranes 408A-408N, one or more cathodes 410A-410N, and one or more bipolar plates 412A-412N. System 400 is described in further detail as follows.

Pump(s) 402A-402B pump anolyte fluid and/or catholyte fluid from anolyte loop 102A and/or catholyte loop 102B via inlet(s) 118A across anode(s) 406A-406N and/or cathode(s) 410A-410N, respectively, and back into anolyte loop 102A and/or catholyte loop 102B via outlet(s) 118B.

Bipolar end plate(s) 404A-404B are connected to DC bus 206 and are configured to conduct electrical current 120 across the layers of load stack(s) 108 to DC bus 206. In embodiments, oxidation of the anolyte fluid flowing across anode(s) 306A-306N occurs to produce free ions that flow across membrane(s) 308A-308N, where reduction of the catholyte fluid flowing across cathode(s) 310A-310N occurs. In embodiments, electrical current 120 flows from bipolar end plate 404A to DC bus 206. In embodiments, bipolar end plate(s) 404A-404B are made of a material and/or combination of materials (e.g., metal, metal alloys, carbon-based materials, conductive polymers, composites, etc.) appropriate for conducting electrical current across load stack(s) 110. This process discharges the electrolyte fluid(s) by decreasing the ionic differential between the anolyte fluid and the catholyte fluid. In embodiments, bipolar end plate(s) 404A-404B are made of the same and/or different material as bipolar end plate(s) 304A-304B.

Anode(s) 406A-406N are configured to facilitate the oxidation of the anolyte fluid in load stack(s) 110. In embodiments, anode(s) 406A-406N are made of a material and/or combination of materials (e.g., metal, metal alloys, carbon-based materials, conductive polymers, organic material, composites, etc.) appropriate for oxidation of the anolyte fluid, and may be made of the same and/or different material as anode(s) 306A-306N and/or cathode(s) 410A-410N. In embodiments, anode(s) 406A-406N are made of a porous material that enables anolyte fluid to flow through anode(s) 406A-406N, thereby increasing the contact area between anode(s) 406A-406N and the anolyte fluid.

Membrane(s) 408A-408N separate anolyte fluid flowing across anode(s) 406A-406N from catholyte fluid flowing across cathode(s) 410A-410N, and enable selective ions to flow from the anolyte fluid to the catholyte fluid in load stack(s) 110. In embodiments, membrane(s) 408A-408N are made of an ion-selective material or composites (e.g., polymers, microporous material, composite polymers, ceramic material, etc.) that allow the passage of specific ions while blocking others, such as, but not limited to, a proton-exchange membrane, a sulfonated tetrafluoroethylene based fluoropolymer-copolymer, and/or the like. In embodiments, membrane(s) 408A-408N are made of the same and/or different materials than membrane(s) 308A-308N. In embodiments, membrane(s) 308A-308N are omitted from load stack(s) 110.

Cathode(s) 410A-410N are configured to facilitate the reduction of the catholyte fluid in load stack(s) 110. In embodiments, cathode(s) 410A-410N are made of a material and/or combination of materials (e.g., metal, metal alloys, carbon-based materials, conductive polymers, organic material, composites, etc.) appropriate for reduction of the catholyte fluid, and may be made of the same and/or different material as cathode(s) 310A-310N and/or anode(s) 406A-406N. In embodiments, cathode(s) 410A-410N are made of a porous material that enables anolyte fluid to flow through cathode(s) 410A-410N, thereby increasing the contact area between cathode(s) 410A-410N and the catholyte fluid.

Bipolar plate(s) 412A-412N separate the electrochemical cells in charging stack(s) 108. In embodiments, bipolar plate(s) 412A-412(N-1) are made of a material and/or combination of materials (e.g., metal, metal alloys, carbon-based materials, conductive polymers, composites, etc.) appropriate for conducting electrical current between the electrochemical cells in charging stack(s) 108. In embodiments, bipolar plate(s) 412A-412(N-1) are made of the same and/or different materials than bipolar plate(s) 312A-312N.

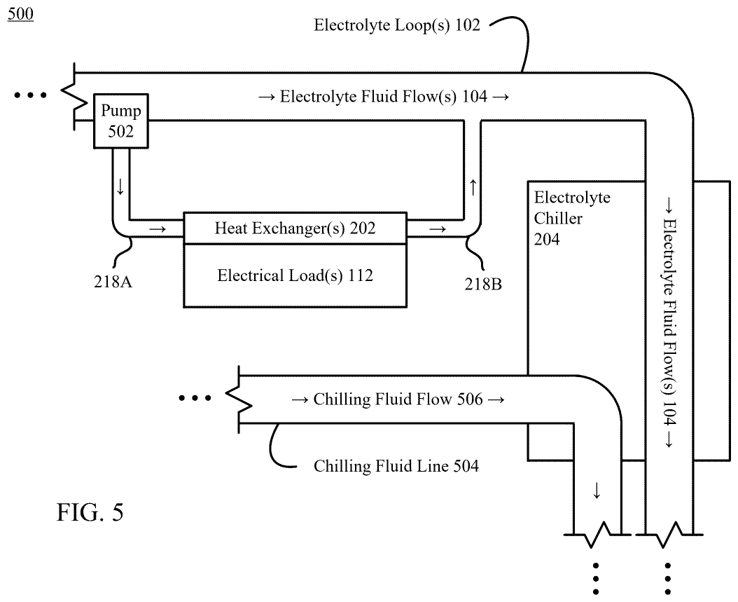

Embodiments described herein may operate in various ways to implement heat transfer using electrolyte fluid. For instance, FIG. 5 depicts a block diagram of a system 500 for heat transfer using electrolyte fluid, in accordance with an embodiment. As shown in FIG. 5, system 500 includes electrolyte loop(s) 102, electrolyte fluid flow(s) 104, electrical load(s) 112, heat exchanger(s) 202, heat exchanger 204, a pump 502, a chilling fluid line 504, and a chilling fluid flow 506. System 500 is described in further detail as follows.

Pump 502 pumps anolyte fluid and/or catholyte fluid from anolyte loop 102A and/or catholyte loop 102B via inlet(s) 218A through heat exchanger(s) 202, and back into anolyte loop 102A and/or catholyte loop 102B via outlet(s) 218B.

Chilling fluid line 504 comprises any structure (e.g., tube, trough, trench, groove, etc.) capable of transporting chilling fluid through heat exchanger 204. In embodiments, chilling fluid line 504 is made of a material and/or combination of materials (e.g., metal, plastic, glass, ceramic, rubber, etc.) appropriate for transporting the chilling fluid.

Chilling fluid flow 506 comprise a movement of chilling fluid flowing through heat exchanger 204. In embodiments, chilling fluid includes, but is not limited to, water, glycol solution, refrigerant, brine solution, and/or any other type of fluid.

Embodiments described herein may operate in various ways to distribute power using electrolyte fluid. For instance, FIG. 6 depicts a flowchart 600 of a process for power distribution using electrolyte fluid, in accordance with an embodiment. Electrolyte loop(s) 102, anolyte loop 102A, catholyte loop 102B, electrolyte fluid flow(s) 104, anolyte fluid flow 104A, catholyte fluid flow 104B, power source(s) 106, charging stack(s) 108, load stack(s) 110, electrical load(s) 112, DC bus 206, pump(s) 212A-212N, pump(s) 302A-302B, bipolar end plate(s) 304A-304B, anode(s) 306A-306N, membrane(s) 308A-308N, cathode(s) 310A-310N, bipolar plate(s) 312A-312(N-1), pump(s) 402A-402B, bipolar end plate(s) 404A-404B, anode(s) 406A-406N, membrane(s) 408A-408N, cathode(s) 410A-410N, and/or bipolar plate(s) 412A-412(N-1) may, for example, operate according to flowchart 600. Flowchart 600 is described as follows with respect to FIGS. 1-4 for illustrative purposes.

Flowchart 600 starts at step 602. In step 602, a first electrolyte fluid is flowed through an electrolyte loop. For instance, electrolyte fluid flow(s) 104 flow through electrolyte loop(s) 102. In embodiments, anolyte fluid flow 104A flows through an anolyte loop 102A and catholyte fluid flow 104B flows through a catholyte loop 102B.

In step 604, the first electrolyte fluid is charged at a charging stack using electricity from an electrical power source. For instance, electrolyte fluid(s) are charged at charging stack(s) 108 using electrical current 114 from power source(s) 106. In embodiments, electrical current 114 flows into bipolar end plate 304A, causing oxidation of the catholyte fluid flowing across cathode(s) 310A-310N which produces free ions that flow across membrane(s) 308A-308N, where reduction of the anolyte fluid flowing across anode(s) 306A-306N occurs. This process recharges the electrolyte fluid(s) by increasing the ionic differential between the anolyte and the catholyte.

In step 606, at a first load stack, electricity is supplied to a first load using electrochemical energy from the first electrolyte fluid. For instance, load stack(s) 110 supplies electrical current 120 to electrical load(s) 112 via DC bus 206. In embodiments, oxidation of the anolyte fluid flowing across anode(s) 306A-306N occurs to produce free ions that flow across membrane(s) 308A-308N, where reduction of the catholyte fluid flowing across cathode(s) 310A-310N occurs. This process results in electrical current 120 flowing from bipolar end plate 404A to DC bus 206.

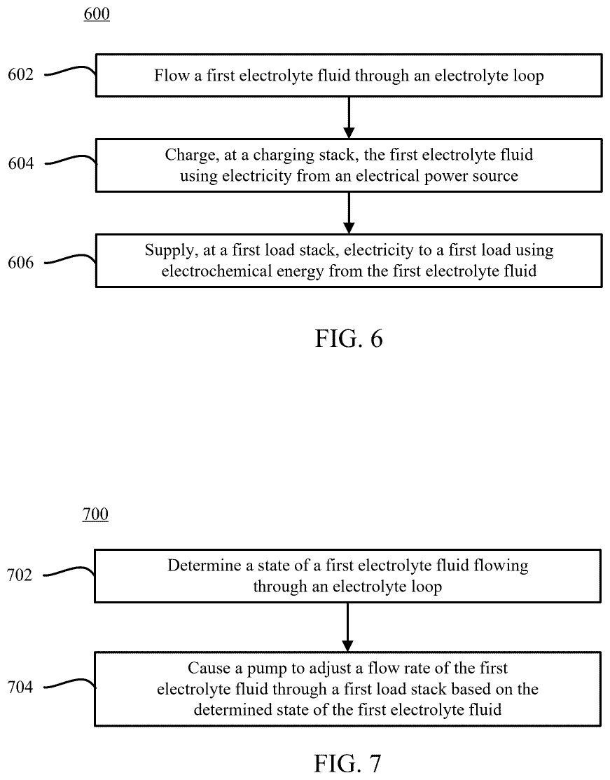

Embodiments described herein may operate in various ways to control a flow rate of electrolyte fluid into a load stack. For instance, FIG. 7 depicts a flowchart 700 of a process for controlling a flow rate of electrolyte fluid into a load stack, in accordance with an embodiment. Sensor(s) 208, controller 210, pump(s) 212A and/or pump(s) 302A-302B may, for example, operate according to flowchart 700. Flowchart 700 is described as follows with respect to FIGS. 1-4 for illustrative purposes.

Flowchart 700 starts at step 702. In step 702, a state of a first electrolyte fluid flowing through an electrolyte loop is determined. For instance, controller 210 determines, via sensor(s) 208, a state of the electrolyte fluid(s) flowing through electrolyte loop(s) 102.

In step 704, a pump is caused to adjust a flow rate of the first electrolyte fluid through a first load stack based on the determined state of the first electrolyte fluid. For instance, controller 210 provides signal(s) 226 to pump(s) 212A to cause pump(s) 212A to adjust the flow rate of the electrolyte fluid(s) across load stack(s) 110.

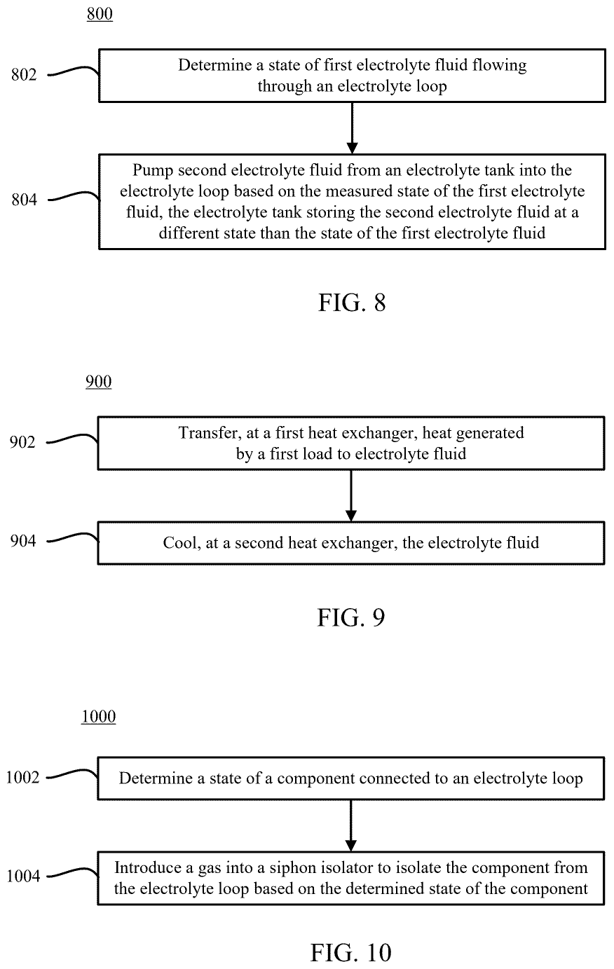

Embodiments described herein may operate in various ways to charge first electrolyte fluid in an electrolyte loop using second electrolyte fluid stored in an electrolyte tank at a higher SOC. For instance, FIG. 8 depicts a flowchart 800 of a process for charging first electrolyte fluid in an electrolyte loop using second electrolyte fluid stored in an electrolyte tank at a higher SOC, in accordance with an embodiment. Sensor(s) 208, controller 210, pump(s) 212B, and/or electrolyte tank(s) 214 may, for example, operate according to flowchart 800. Flowchart 800 is described as follows with respect to FIGS. 1-2 for illustrative purposes.

Flowchart 800 starts at step 802. In step 802, a state of a first electrolyte fluid flowing through an electrolyte loop is determined. For instance, controller 210 determines, via sensor(s) 208, a state of the electrolyte fluid(s) flowing through electrolyte loop(s) 102.

In step 804, a second electrolyte fluid is pumped from an electrolyte tank into the electrolyte loop based on the measured state of the first electrolyte fluid, the electrolyte tank storing the second electrolyte fluid at a different state than the state of the first electrolyte fluid. For instance, controller 210 provides a signal 228 to pump(s) 212B to cause pump(s) 212B to pump electrolyte fluid(s) stored in electrolyte tank(s) 214 into electrolyte loop(s) 102. In embodiments, additional electrolyte fluid(s) are stored in electrolyte tank(s) 214 at a higher SOC (e.g., 90% SOC, 100% SOC, etc.) to provide protection from power shortage and/or outages. For instance, when power provided by power source(s) 106 and/or charging stack(s) 108 is insufficient to charge the electrolyte fluid(s) in the electrolyte loop(s) 102, the electrolyte fluid(s) stored in electrolyte tank(s) 214 at the higher SOC are pumped into electrolyte loop(s) 102 to increase the SOC of the electrolyte fluid flowing through electrolyte loop(s) 102.

Embodiments described herein may operate in various ways to implement heat transfer using electrolyte fluid. For instance, FIG. 9 depicts a flowchart 900 of a process for heat transfer using electrolyte fluid, in accordance with an embodiment. Electrolyte loop(s) 102, electrolyte fluid flow(s) 104, electrical load(s) 112, heat exchanger(s) 202, heat exchanger 204, pump 502, chilling fluid line 504, and/or chilling fluid flow 506 may, for example, operate according to flowchart 900. Flowchart 900 is described as follows with respect to FIGS. 1, 2, and 5 for illustrative purposes.

Flowchart 900 starts at step 902. In step 902, at a first heat exchanger, heat is transferred from a first load to electrolyte fluid. For instance, heat generated by electrical load(s) 112 are transferred at heat exchanger(s) 202 to electrolyte fluid(s) flowing through electrolyte loop(s) 102.

In step 904, the electrolyte fluid is cooled at a second heat exchanger. For instance, electrolyte fluid(s) flowing through electrolyte loop(s) 102 are cooled at heat exchanger 204. In embodiments, the electrolyte fluid(s) are cooled using chilling fluid flow 506 flowing through chilling fluid line 504 via a second heat exchanger, such as, but not limited to, a shell-and-tube heat exchanger, a plate heat exchanger, a double-pipe heat exchanger, a parallel-flow heat exchanger, a counterflow heat exchanger, an air-cooled heat exchanger, a rear door heat exchanger, and/or the like. In embodiments, heat transferred to chilling fluid flow 506 is used for other purposes, such as, but not limited to, heating water, heating air, heating buildings, heating sidewalks, and/or the like.

Embodiments described herein may operate in various ways to isolate an electrolyte fluid leak. For instance, FIG. 10 depicts a flowchart 1000 of a process for isolating an electrolyte fluid leak, in accordance with an embodiment. Sensor(s) 208, controller 210, pump(s) 212A and/or isolator(s) 216 may, for example, operate according to flowchart 1000. Flowchart 1000 is described as follows with respect to FIGS. 1-2 for illustrative purposes.

Flowchart 1000 starts at step 1002. In step 1002, a state of a component connected to an electrolyte loop is determined. For instance, controller 210 determines a state (e.g., failure, leak, etc.) of a component of system(s) 100 and/or 200 based on system state information 222 received from sensor(s) 208.

In step 1004, a gas is introduced into a syphon isolator to isolate the component from the electrolyte loop based on the determined state of the component. For instance, controller 210 causes isolator(s) 216 to isolate a component of system(s) 100 and/or 200 from electrolyte loop(s) 102 based on the determined state of the component. In embodiments, controller 210 provides an alert to a service technician that manually introduces a gas into siphon isolator 216 to isolate the component from electrolyte loop(s) 102. In embodiments, controller 210 provides a signal 230 to isolator(s) 216 to cause isolator(s) 216 to automatically pump a gas into isolator(s) 216 to isolate the component from electrolyte loop(s) 102.

### III. Example Mobile Device and Computer System Implementation

Controller 210, and/or components described therein, and/or the steps of flowcharts 700, 800, and/or 1000 are implemented in hardware, or hardware combined with one or both of software and/or firmware. For example, controller 210, and/or the components described therein, and/or the steps of flowcharts 700, 800, and/or 1000 are each implemented as computer program code/instructions configured to be executed in one or more processors and stored in a computer readable storage medium. Alternatively, electrical load(s) 112, controller 210, and/or the components described therein, and/or the steps of flowcharts 700, 800, and/or 1000 are implemented in one or more SoCs (system on chip). An SoC includes an integrated circuit chip that includes one or more of a processor (e.g., a central processing unit (CPU), microcontroller, microprocessor, digital signal processor (DSP), etc.), memory, one or more communication interfaces, and/or further circuits, and optionally executes received program code and/or include embedded firmware to perform functions.

Embodiments disclosed herein can be implemented in one or more computing devices that are mobile (a mobile device) and/or stationary (a stationary device) and include any combination of the features of such mobile and stationary computing devices. Examples of computing devices in which embodiments are implementable are described as follows with respect to FIG. 11. FIG. 11 shows a block diagram of an exemplary computing environment 1100 that includes a computing device 1102. Computing device 1102 is an example of controller 210, and/or electrical load(s) 112, which each include one or more of the components of computing device 1102. In some embodiments, computing device 1102 is communicatively coupled with devices (not shown in FIG. 11) external to computing environment 1100 via network 1104. Network 1104 comprises one or more networks such as local area networks (LANs), wide area networks (WANs), enterprise networks, the Internet, etc. In examples, network 1104 includes one or more wired and/or wireless portions. In some examples, network 1104 additionally or alternatively includes a cellular network for cellular communications. Computing device 1102 is described in detail as follows.

Computing device 1102 can be any of a variety of types of computing devices. Examples of computing device 1102 include a mobile computing device such as a handheld computer (e.g., a personal digital assistant (PDA)), a laptop computer, a tablet computer, a hybrid device, a notebook computer, a netbook, a mobile phone (e.g., a cell phone, a smart phone, etc.), a wearable computing device (e.g., a head-mounted augmented reality and/or virtual reality device including smart glasses), or other type of mobile computing device. In an alternative example, computing device 1102 is a stationary computing device such as a desktop computer, a personal computer (PC), a stationary server device, a minicomputer, a mainframe, a supercomputer, etc.

As shown in FIG. 11, computing device 1102 includes a variety of hardware and software components, including a processor 1110, a storage 1120, a graphics processing unit (GPU) 1142, a neural processing unit (NPU) 1144, one or more input devices 1130, one or more output devices 1150, one or more wireless modems 1160, one or more wired interfaces 1180, a power supply 1182, a location information (LI) receiver 1184, and an accelerometer 1186. Storage 1120 includes memory 1156, which includes non-removable memory 1122 and removable memory 1124, and a storage device 1188. Storage 1120 also stores an operating system 1112, application programs 1114, and application data 1116. Wireless modem(s) 1160 include a Wi-Fi modem 1162, a Bluetooth modem 1164, and a cellular modem 1166. Output device(s) 1150 includes a speaker 1152 and a display 1154. Input device(s) 1130 includes a touch screen 1132, a microphone 1134, a camera 1136, a physical keyboard 1138, and a trackball 1140. Not all components of computing device 1102 shown in FIG. 11 are present in all embodiments, additional components not shown may be present, and in a particular embodiment any combination of the components are present. In examples, components of computing device 1102 are mounted to a circuit card (e.g., a motherboard) of computing device 1102, integrated in a housing of computing device 1102, or otherwise included in computing device 1102. The components of computing device 1102 are described as follows.

In embodiments, a single processor 1110 (e.g., central processing unit (CPU), microcontroller, a microprocessor, signal processor, ASIC (application specific integrated circuit), and/or other physical hardware processor circuit) or multiple processors 1110 are present in computing device 1102 for performing such tasks as program execution, signal coding, data processing, input/output processing, power control, and/or other functions. In examples, processor 1110 is a single-core or multi-core processor, and each processor core is single-threaded or multithreaded (to provide multiple threads of execution concurrently). Processor 1110 is configured to execute program code stored in a computer readable medium, such as program code of operating system 1112 and application programs 1114 stored in storage 1120. The program code is structured to cause processor 1110 to perform operations, including the processes/methods disclosed herein. Operating system 1112 controls the allocation and usage of the components of computing device 1102 and provides support for one or more application programs 1114 (also referred to as “applications” or “apps”). In examples, application programs 1114 include common computing applications (e.g., e-mail applications, calendars, contact managers, web browsers, messaging applications), further computing applications (e.g., word processing applications, mapping applications, media player applications, productivity suite applications), one or more machine learning (ML) models, as well as applications related to the embodiments disclosed elsewhere herein. In examples, processor(s) 1110 includes one or more general processors (e.g., CPUs) configured with or coupled to one or more hardware accelerators, such as one or more NPUs 1144 and/or one or more GPUs 1142.

Any component in computing device 1102 can communicate with any other component according to function, although not all connections are shown for ease of illustration. For instance, as shown in FIG. 11, bus 1106 is a multiple signal line communication medium (e.g., conductive traces in silicon, metal traces along a motherboard, wires, etc.) present to communicatively couple processor 1110 to various other components of computing device 1102, although in other embodiments, an alternative bus, further buses, and/or one or more individual signal lines is/are present to communicatively couple components. Bus 1106 represents one or more of any of several types of bus structures, including a memory bus or memory controller, a peripheral bus, an accelerated graphics port, and a processor or local bus using any of a variety of bus architectures.

Storage 1120 is physical storage that includes one or both of memory 1156 and storage device 1188, which store operating system 1112, application programs 1114, and application data 1116 according to any distribution. Non-removable memory 1122 includes one or more of RAM (random access memory), ROM (read only memory), flash memory, a solid-state drive (SSD), a hard disk drive (e.g., a disk drive for reading from and writing to a hard disk), and/or other physical memory device type. In examples, non-removable memory 1122 includes main memory and is separate from or fabricated in a same integrated circuit as processor 1110. As shown in FIG. 11, non-removable memory 1122 stores firmware 1118 that is present to provide low-level control of hardware. Examples of firmware 1118 include BIOS (Basic Input/Output System, such as on personal computers) and boot firmware (e.g., on smart phones). In examples, removable memory 1124 is inserted into a receptacle of or is otherwise coupled to computing device 1102 and can be removed by a user from computing device 1102. Removable memory 1124 can include any suitable removable memory device type, including an SD (Secure Digital) card, a Subscriber Identity Module (SIM) card, which is well known in GSM (Global System for Mobile Communications) communication systems, and/or other removable physical memory device type. In examples, one or more of storage device 1188 are present that are internal and/or external to a housing of computing device 1102 and are or are not removable. Examples of storage device 1188 include a hard disk drive, a SSD, a thumb drive (e.g., a USB (Universal Serial Bus) flash drive), or other physical storage device.

One or more programs are stored in storage 1120. Such programs include operating system 1112, one or more application programs 1114, and other program modules and program data. Examples of such application programs include computer program logic (e.g., computer program code/instructions) for implementing power source(s) 106, charging stack(s) 108, load stack(s) 110, electrical load(s) 112A-N, heat exchanger(s) 202, heat exchanger 204, DC bus 206, sensor(s) 208, controller 210, pump(s) 212A-212N, isolator(s) 216, pump(s) 302A-302B, pump(s) 402A-402B, pump 502, and/or each of the components described therein, as well as any of flowcharts 600, 700, 800, 900, and/or 1000, and/or any individual steps thereof.

Storage 1120 also stores data used and/or generated by operating system 1112 and application programs 1114 as application data 1116. Examples of application data 1116 include web pages, text, images, tables, sound files, video data, and other data. In examples, application data 1116 is sent to and/or received from one or more network servers or other devices via one or more wired or wireless networks. Storage 1120 can be used to store further data including a subscriber identifier, such as an International Mobile Subscriber Identity (IMSI), and an equipment identifier, such as an International Mobile Equipment Identifier (IMEI). Such identifiers can be transmitted to a network server to identify users and equipment.

In examples, a user enters commands and information into computing device 1102 through one or more input devices 1130 and receives information from computing device 1102 through one or more output devices 1150. Input device(s) 1130 includes one or more of touch screen 1132, microphone 1134, camera 1136, physical keyboard 1138 and/or trackball 1140 and output device(s) 1150 includes one or more of speaker 1152 and display 1154. Each of input device(s) 1130 and output device(s) 1150 are integral to computing device 1102 (e.g., built into a housing of computing device 1102) or are external to computing device 1102 (e.g., communicatively coupled wired or wirelessly to computing device 1102 via wired interface(s) 1180 and/or wireless modem(s) 1160). Further input devices 1130 (not shown) can include a Natural User Interface (NUI), a pointing device (computer mouse), a joystick, a video game controller, a scanner, a touch pad, a stylus pen, a voice recognition system to receive voice input, a gesture recognition system to receive gesture input, or the like. Other possible output devices (not shown) can include piezoelectric or other haptic output devices. Some devices can serve more than one input/output function. For instance, display 1154 displays information, as well as operating as touch screen 1132 by receiving user commands and/or other information (e.g., by touch, finger gestures, virtual keyboard, etc.) as a user interface. Any number of each type of input device(s) 1130 and output device(s) 1150 are present, including multiple microphones 1134, multiple cameras 1136, multiple speakers 1152, and/or multiple displays 1154.

In embodiments where GPU 1142 is present, GPU 1142 includes hardware (e.g., one or more integrated circuit chips that implement one or more of processing cores, multiprocessors, compute units, etc.) configured to accelerate computer graphics (two-dimensional (2D) and/or three-dimensional (3D)), perform image processing, and/or execute further parallel processing applications (e.g., training of neural networks, etc.). Examples of GPU 1142 perform calculations related to 3D computer graphics, include 2D acceleration and framebuffer capabilities, accelerate memory-intensive work of texture mapping and rendering polygons, accelerate geometric calculations such as the rotation and translation of vertices into different coordinate systems, support programmable shaders that manipulate vertices and textures, perform oversampling and interpolation techniques to reduce aliasing, and/or support very high-precision color spaces.

In examples, NPU 1144 (also referred to as an “artificial intelligence (AI) accelerator” or “deep learning processor (DLP)”) is a processor or processing unit configured to accelerate artificial intelligence and machine learning applications, such as execution of machine learning (ML) model (MLM) 1128. In an example, NPU 1144 is configured for a data-driven parallel computing and is highly efficient at processing massive multimedia data such as videos and images and processing data for neural networks. NPU 1144 is configured for efficient handling of AI-related tasks, such as speech recognition, background blurring in video calls, photo or video editing processes like object detection, etc.

In embodiments disclosed herein that implement ML models, NPU 1144 can be utilized to execute such ML models, of which MLM 1128 is an example. For instance, where applicable, MLM 1128 is a generative AI model that generates content that is complex, coherent, and/or original. For instance, a generative AI model can create sophisticated sentences, lists, ranges, tables of data, images, essays, and/or the like. An example of a generative AI model is a language model. A language model is a model that estimates the probability of a token or sequence of tokens occurring in a longer sequence of tokens. In this context, a “token” is an atomic unit that the model is training on and making predictions on. Examples of a token include, but are not limited to, a word, a character (e.g., an alphanumeric character, a blank space, a symbol, etc.), a sub-word (e.g., a root word, a prefix, or a suffix). In other types of models (e.g., image based models) a token may represent another kind of atomic unit (e.g., a subset of an image). Examples of language models applicable to embodiments herein include large language models (LLMs), text-to-image AI image generation systems, text-to-video AI generation systems, etc. A large language model (LLM) is a language model that has a high number of model parameters. In examples, an LLM has millions, billions, trillions, or even greater numbers of model parameters. Model parameters of an LLM are the weights and biases the model learns during training. Some implementations of LLMs are transformer-based LLMs (e.g., the family of generative pre-trained transformer (GPT) models). A transformer is a neural network architecture that relies on self-attention mechanisms to transform a sequence of input embeddings into a sequence of output embeddings (e.g., without relying on convolutions or recurrent neural networks).

In further examples, NPU 1144 is used to train MLM 1128. To train MLM 1128, training data is that includes input features (attributes) and their corresponding output labels/target values (e.g., for supervised learning) is collected. A training algorithm is a computational procedure that is used so that MLM 1128 learns from the training data. Parameters/weights are internal settings of MLM 1128 that are adjusted during training by the training algorithm to reduce a difference between predictions by MLM 1128 and actual outcomes (e.g., output labels). In some examples, MLM 1128 is set with initial values for the parameters/weights. A loss function measures a dissimilarity between predictions by MLM 1128 and the target values, and the parameters/weights of MLM 1128 are adjusted to minimize the loss function. The parameters/weights are iteratively adjusted by an optimization technique, such as gradient descent. In this manner, MLM 1128 is generated through training by NPU 1144 to be used to generate inferences based on received input feature sets for particular applications. MLM 1128 is generated as a computer program or other type of algorithm configured to generate an output (e.g., a classification, a prediction/inference) based on received input features, and is stored in the form of a file or other data structure.

In examples, such training of MLM 1128 by NPU 1144 is supervised or unsupervised. According to supervised learning, input objects (e.g., a vector of predictor variables) and a desired output value (e.g., a human-labeled supervisory signal) train MLM 1128. The training data is processed, building a function that maps new data on expected output values. Example algorithms usable by NPU 1144 to perform supervised training of MLM 1128 in particular implementations include support-vector machines, linear regression, logistic regression, Naïve Bayes, linear discriminant analysis, decision trees, K-nearest neighbor algorithm, neural networks, and similarity learning.

In an example of supervised learning where MLM 1128 is an LLM, MLM 1128 can be trained by exposing the LLM to (e.g., large amounts of) text (e.g., predetermined datasets, books, articles, text-based conversations, webpages, transcriptions, forum entries, and/or any other form of text and/or combinations thereof). In examples, training data is provided from a database, from the Internet, from a system, and/or the like. Furthermore, an LLM can be fine-tuned using Reinforcement Learning with Human Feedback (RLHF), where the LLM is provided the same input twice and provides two different outputs and a user ranks which output is preferred. In this context, the user's ranking is utilized to improve the model. Further still, in example embodiments, an LLM is trained to perform in various styles, e.g., as a completion model (a model that is provided a few words or tokens and generates words or tokens to follow the input), as a conversation model (a model that provides an answer or other type of response to a conversation-style prompt), as a combination of a completion and conversation model, or as another type of LLM model.

According to unsupervised learning, MLM 1128 is trained to learn patterns from unlabeled data. For instance, in embodiments where MLM 1128 implements unsupervised learning techniques, MLM 1128 identifies one or more classifications or clusters to which an input belongs. During a training phase of MLM 1128 according to unsupervised learning, MLM 1128 tries to mimic the provided training data and uses the error in its mimicked output to correct itself (i.e., correct weights and biases). In further examples, NPU 1144 perform unsupervised training of MLM 1128 according to one or more alternative techniques, such as Hopfield learning rule, Boltzmann learning rule, Contrastive Divergence, Wake Sleep, Variational Inference, Maximum Likelihood, Maximum A Posteriori, Gibbs Sampling, and backpropagating reconstruction errors or hidden state reparameterizations.

Note that NPU 1144 need not necessarily be present in all ML model embodiments. In embodiments where ML models are present, any one or more of processor 1110, GPU 1142, and/or NPU 1144 can be present to train and/or execute MLM 1128.

One or more wireless modems 1160 can be coupled to antenna(s) (not shown) of computing device 1102 and can support two-way communications between processor 1110 and devices external to computing device 1102 through network 1104, as would be understood to persons skilled in the relevant art(s). Wireless modem 1160 is shown generically and can include a cellular modem 1166 for communicating with one or more cellular networks, such as a GSM network for data and voice communications within a single cellular network, between cellular networks, or between the mobile device and a public switched telephone network (PSTN). In examples, wireless modem 1160 also or alternatively includes other radio-based modem types, such as a Bluetooth modem 1164 (also referred to as a “Bluetooth device”) and/or Wi-Fi modem 1162 (also referred to as an “wireless adaptor”). Wi-Fi modem 1162 is configured to communicate with an access point or other remote Wi-Fi-capable device according to one or more of the wireless network protocols based on the IEEE (Institute of Electrical and Electronics Engineers) 802.11 family of standards, commonly used for local area networking of devices and Internet access. Bluetooth modem 1164 is configured to communicate with another Bluetooth-capable device according to the Bluetooth short-range wireless technology standard(s) such as IEEE 802.15.1 and/or managed by the Bluetooth Special Interest Group (SIG).

Computing device 1102 can further include power supply 1182, LI receiver 1184, accelerometer 1186, and/or one or more wired interfaces 1180. Example wired interfaces 1180 include a USB port, IEEE 1394 (FireWire) port, a RS-232 port, an HDMI (High-Definition Multimedia Interface) port (e.g., for connection to an external display), a DisplayPort port (e.g., for connection to an external display), an audio port, and/or an Ethernet port, the purposes and functions of each of which are well known to persons skilled in the relevant art(s). Wired interface(s) 1180 of computing device 1102 provide for wired connections between computing device 1102 and network 1104, or between computing device 1102 and one or more devices/peripherals when such devices/peripherals are external to computing device 1102 (e.g., a pointing device, display 1154, speaker 1152, camera 1136, physical keyboard 1138, etc.). Power supply 1182 is configured to supply power to each of the components of computing device 1102 and receives power from a battery internal to computing device 1102, and/or from a power cord plugged into a power port of computing device 1102 (e.g., a USB port, an A/C power port). LI receiver 1184 is useable for location determination of computing device 1102 and in examples includes a satellite navigation receiver such as a Global Positioning System (GPS) receiver and/or includes other type of location determiner configured to determine location of computing device 1102 based on received information (e.g., using cell tower triangulation, etc.). Accelerometer 1186, when present, is configured to determine an orientation of computing device 1102.

Note that the illustrated components of computing device 1102 are not required or all-inclusive, and fewer or greater numbers of components can be present as would be recognized by one skilled in the art. In examples, computing device 1102 includes one or more of a gyroscope, barometer, proximity sensor, ambient light sensor, digital compass, etc. In an example, processor 1110 and memory 1156 are co-located in a same semiconductor device package, such as being included together in an integrated circuit chip, FPGA, or system-on-chip (SOC), optionally along with further components of computing device 1102.

In embodiments, computing device 1102 is configured to implement any of the above-described features of flowcharts herein. Computer program logic for performing any of the operations, steps, and/or functions described herein is stored in storage 1120 and executed by processor 1110.

In some embodiments, server infrastructure 1170 is present in computing environment 1100 and is communicatively coupled with computing device 1102 via network 1104. Server infrastructure 1170, when present, is a network-accessible server set (e.g., a cloud-based environment or platform). As shown in FIG. 11, server infrastructure 1170 includes clusters 1172. Each of clusters 1172 comprises a group of one or more compute nodes and/or a group of one or more storage nodes. For example, as shown in FIG. 11, cluster 1172 includes nodes 1174. Each of nodes 1174 are accessible via network 1104 (e.g., in a “cloud-based” embodiment) to build, deploy, and manage applications and services. In examples, any of nodes 1174 is a storage node that comprises a plurality of physical storage disks, SSDs, and/or other physical storage devices that are accessible via network 1104 and are configured to store data associated with the applications and services managed by nodes 1174.

Each of nodes 1174, as a compute node, comprises one or more server computers, server systems, and/or computing devices. For instance, a node 1174 in accordance with an embodiment includes one or more of the components of computing device 1102 disclosed herein. Each of nodes 1174 is configured to execute one or more software applications (or “applications”) and/or services and/or manage hardware resources (e.g., processors, memory, etc.), which are utilized by users (e.g., customers) of the network-accessible server set. In examples, as shown in FIG. 11, nodes 1174 includes a node 1146 that includes storage 1148 and/or one or more of a processor 1158 (e.g., similar to processor 1110, GPU 1142, and/or NPU 1144 of computing device 1102). Storage 1148 stores application programs 1176 and application data 1178. Processor(s) 1158 operate application programs 1176 which access and/or generate related application data 1178. In an implementation, nodes such as node 1146 of nodes 1174 operate or comprise one or more virtual machines, with each virtual machine emulating a system architecture (e.g., an operating system), in an isolated manner, upon which applications such as application programs 1176 are executed.

In embodiments, one or more of clusters 1172 are located/co-located (e.g., housed in one or more nearby buildings with associated components such as backup power supplies, redundant data communications, environmental controls, etc.) to form a datacenter, or are arranged in other manners. Accordingly, in an embodiment, one or more of clusters 1172 are included in a datacenter in a distributed collection of datacenters. In embodiments, exemplary computing environment 1100 comprises part of a cloud-based platform.

In an embodiment, computing device 1102 accesses application programs 1176 for execution in any manner, such as by a client application and/or a browser at computing device 1102.

In an example, for purposes of network (e.g., cloud) backup and data security, computing device 1102 additionally and/or alternatively synchronizes copies of application programs 1114 and/or application data 1116 to be stored at network-based server infrastructure 1170 as application programs 1176 and/or application data 1178. In examples, operating system 1112 and/or application programs 1114 include a file hosting service client configured to synchronize applications and/or data stored in storage 1120 at network-based server infrastructure 1170.

In some embodiments, on-premises servers 1192 are present in computing environment 1100 and are communicatively coupled with computing device 1102 via network 1104. On-premises servers 1192, when present, are hosted within an organization's infrastructure and, in many cases, physically onsite of a facility of that organization. On-premises servers 1192 are controlled, administered, and maintained by IT (Information Technology) personnel of the organization or an IT partner to the organization. Application data 1198 can be shared by on-premises servers 1192 between computing devices of the organization, including computing device 1102 (when part of an organization) through a local network of the organization, and/or through further networks accessible to the organization (including the Internet). Furthermore, in examples, on-premises servers 1192 serve applications such as application programs 1196 to the computing devices of the organization, including computing device 1102. Accordingly, in examples, on-premises servers 1192 include storage 1194 (which includes one or more physical storage devices such as storage disks and/or SSDs) for storage of application programs 1196 and application data 1198 and include a processor 1190 (e.g., similar to processor 1110, GPU 1142, and/or NPU 1144 of computing device 1102) for execution of application programs 1196. In some embodiments, multiple processors 1190 are present for execution of application programs 1196 and/or for other purposes. In further examples, computing device 1102 is configured to synchronize copies of application programs 1114 and/or application data 1116 for backup storage at on-premises servers 1192 as application programs 1196 and/or application data 1198.

Embodiments described herein may be implemented in one or more of computing device 1102, network-based server infrastructure 1170, and on-premises servers 1192. For example, in some embodiments, computing device 1102 is used to implement systems, clients, or devices, or components/subcomponents thereof, disclosed elsewhere herein. In other embodiments, a combination of computing device 1102, network-based server infrastructure 1170, and/or on-premises servers 1192 is used to implement the systems, clients, or devices, or components/subcomponents thereof, disclosed elsewhere herein.

As used herein, the terms “computer program medium,” “computer-readable medium,” “computer-readable storage medium,” and “computer-readable storage device,” etc., are used to refer to physical hardware media. Examples of such physical hardware media include any hard disk, optical disk, SSD, other physical hardware media such as RAMs, ROMs, flash memory, digital video disks, zip disks, MEMs (microelectronic machine) memory, nanotechnology-based storage devices, and further types of physical/tangible hardware storage media of storage 1120. Such computer-readable media and/or storage media are distinguished from and non-overlapping with communication media, propagating signals, and signals per se. Stated differently, “computer program medium,” “computer-readable medium,” “computer-readable storage medium,” and “computer-readable storage device” do not encompass communication media, propagating signals, and signals per se. Communication media embodies computer-readable instructions, data structures, program modules or other data in a modulated data signal such as a carrier wave. The term “modulated data signal” means a signal that has one or more of its characteristics set or changed in such a manner as to encode information in the signal. By way of example, and not limitation, communication media includes wireless media such as acoustic, RF, infrared, and other wireless media, as well as wired media. Embodiments are also directed to such communication media that are separate and non-overlapping with embodiments directed to computer-readable storage media.

As noted above, computer programs and modules (including application programs 1114) are stored in storage 1120. Such computer programs can also be received via wired interface(s) 1160 and/or wireless modem(s) 1160 over network 1104. Such computer programs, when executed or loaded by an application, enable computing device 1102 to implement features of embodiments discussed herein. Accordingly, such computer programs represent controllers of the computing device 1102.

Embodiments are also directed to computer program products comprising computer code or instructions stored on any computer-readable medium or computer-readable storage medium. Such computer program products include the physical storage of storage 1120 as well as further physical storage types.

### IV. Additional Example Embodiments

In embodiments, a system comprises: an electrolyte loop comprising first electrolyte fluid flowing through the electrolyte loop; a charging stack configured to charge the first electrolyte fluid using electricity from an electrical power source; and a first load stack configured to supply electricity to a first load using electrochemical energy from the first electrolyte fluid.

In embodiments, the system further comprises: a second load stack; a second load; and a DC electrical bus connected to the first load stack, the first load, the second load stack, and the second load, wherein the first load stack and the second load stack supply DC electrical power to the DC electrical bus, and the DC electrical bus supplies DC electrical power to the first load and the second load.

In embodiments, the system further comprises: a sensor configured to measure a state of the first electrolyte fluid; a pump configured to pump the first electrolyte fluid through the first load stack; and a controller configured to cause the pump to adjust a flow rate of the first electrolyte fluid through the first load stack based on the measured state of the first electrolyte fluid.

In embodiments, the system further comprises: a sensor configured to measure a state of the first electrolyte fluid; an electrolyte tank storing second electrolyte fluid at a different state than the state of the first electrolyte fluid; a pump configured to pump the second electrolyte fluid into the electrolyte loop; and a controller configured to cause the pump to pump the second electrolyte fluid into the electrolyte loop based on the measured state of the first electrolyte fluid.

In embodiments, the first load comprises at least one of: a server; a server rack; a central processing unit; a graphics processing unit; a Tensor processing unit; a neural processing unit; a storage cluster; a network component; a DC to DC converter; a DC to alternating current (AC) inverter; an air handling unit; an administrative load; lighting; or a heating system.

In embodiments, the system further comprises: a first heat exchanger configured to transfer heat generated by the first load to the first electrolyte fluid; and a second heat exchanger configured to transfer heat from the first electrolyte fluid.

In embodiments, the electrolyte loop comprises at least one of: an anolyte loop, wherein the first electrolyte fluid comprises an anolyte fluid flowing through the anolyte loop; or a catholyte loop, wherein the first electrolyte fluid comprises a catholyte fluid flowing through the catholyte loop.

In embodiments, the first electrolyte fluid comprises an additive, the additive designed to react with ambient air outside of the electrolyte loop to patch a leak of the first electrolyte fluid.

In embodiments, the system further comprises: a sensor to determine a state of a component connected to the electrolyte loop; and a siphon isolator configured to isolate the component from the electrolyte loop based on the determined state of the component.

In embodiments, a method comprises: flowing a first electrolyte fluid through an electrolyte loop; charging, at a charging stack the first electrolyte fluid using electricity from an electrical power source; and supplying, at a first load stack, electricity to a first load using electrochemical energy from the first electrolyte fluid.

In embodiments, supplying, at a first load stack, electricity to a first load comprises: supplying, at the first load stack, electricity to a DC electrical bus, and the DC electrical bus supplies DC electrical power to the first load and a second load.

In embodiments, the method further comprises: determining a state of the first electrolyte fluid; and causing a pump to adjust a flow rate of the first electrolyte fluid through the first load stack based on the determined state of the first electrolyte fluid.

In embodiments, the method further comprises: determining a state of the first electrolyte fluid; and pumping second electrolyte fluid from an electrolyte tank into the electrolyte loop based on the measured state of the first electrolyte fluid, the electrolyte tank storing the second electrolyte fluid at a different state than the state of the first electrolyte fluid.

In embodiments, the first load comprises at least one of: a server; a server rack; a central processing unit; a graphics processing unit; a Tensor processing unit; a neural processing unit; a storage cluster; a network component; a DC to DC converter; a DC to alternating current (AC) inverter; an air handling unit; an administrative load; lighting; or a heating system.

In embodiments, the method further comprises: transferring, at a first heat exchanger, heat generated by the first load to the first electrolyte fluid; and cooling, at a second heat exchanger, the first electrolyte fluid.

In embodiments, flowing a first electrolyte fluid through an electrolyte loop comprises at least one of: flowing an anolyte fluid through an anolyte loop; or flowing a catholyte fluid through a catholyte loop In embodiments, the method further comprises: adding, to the first electrolyte fluid, an additive designed to react with ambient air outside of the electrolyte loop to patch a leak of the first electrolyte fluid.

In embodiments, the method further comprises: determine a state of a component connected to the electrolyte loop; and introducing a gas into a siphon isolator to isolate the component from the electrolyte loop based on the determined state of the component.

In embodiments, a datacenter comprises: a DC electrical bus supplying DC electrical power to an electrical load; a first load stack configured to supply electricity to the DC electrical bus using electrochemical energy from electrolyte fluid flowing through an electrolyte loop; and a charging stack configured to charge the electrolyte fluid using electricity from an electrical power source.

In embodiments, the datacenter comprises: a first heat exchanger configured to transfer heat generated by the server component to the electrolyte fluid; and a second heat exchanger configured to cool the electrolyte fluid.

### V. Conclusion

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment for an application for which it is intended. Furthermore, where “based on” is used to indicate an effect being a result of an indicated cause, it is to be understood that the effect is not required to only result from the indicated cause, but that any number of possible additional causes may also contribute to the effect. Thus, as used herein, the term “based on” should be understood to be equivalent to the term “based at least on.”

While various embodiments of the present disclosure have been described above, it should be understood that they have been presented by way of example only, and not limitation. It will be understood by those skilled in the relevant art(s) that various changes in form and details may be made therein without departing from the spirit and scope of the invention as defined in the appended claims. Accordingly, the breadth and scope of the present invention should not be limited by any of the above-described exemplary embodiments, but should be defined only in accordance with the following claims and their equivalents.

What is claimed is:

1. A system comprising:
an electrolyte loop comprising first electrolyte fluid flowing through the electrolyte loop;
a charging stack configured to charge the first electrolyte fluid using electricity from an electrical power source; and
a first load stack configured to supply electricity to a first load using electrochemical energy from the first electrolyte fluid.

2. The system of claim 1, further comprising:
a second load stack;
a second load; and
a direct current (DC) electrical bus connected to the first load stack, the first load, the second load stack, and the second load,
wherein the first load stack and the second load stack supply DC electrical power to the DC electrical bus, and the DC electrical bus supplies DC electrical power to the first load and the second load.

3. The system of claim 1, further comprising:
a sensor configured to measure a state of the first electrolyte fluid;
a pump configured to pump the first electrolyte fluid through the first load stack; and
a controller configured to cause the pump to adjust a flow rate of the first electrolyte fluid through the first load stack based on the measured state of the first electrolyte fluid.

4. The system of claim 1, further comprising:
a sensor configured to measure a state of the first electrolyte fluid;
an electrolyte tank storing second electrolyte fluid at a different state than the state of the first electrolyte fluid;
a pump configured to pump the second electrolyte fluid into the electrolyte loop; and
a controller configured to cause the pump to pump the second electrolyte fluid into the electrolyte loop based on the measured state of the first electrolyte fluid.

5. The system of claim 1, wherein the first load comprises at least one of:
a server;
a server rack;
a central processing unit;
a graphics processing unit;
a Tensor processing unit,
a neural processing unit;
a storage cluster;
a network component;
a DC to DC converter;
a DC to alternating current (AC) inverter;
an air handling unit;
an administrative load;
lighting; or
a heating system.

6. The system of claim 1, further comprising:
a first heat exchanger configured to transfer heat generated by the first load to the first electrolyte fluid; and
a second heat exchanger configured to transfer heat from the first electrolyte fluid.

7. The system of claim 1, wherein the electrolyte loop comprises at least one of:
an anolyte loop, wherein the first electrolyte fluid comprises an anolyte fluid flowing through the anolyte loop; or
a catholyte loop, wherein the first electrolyte fluid comprises a catholyte fluid flowing through the catholyte loop.

8. The system of claim 1, wherein the first electrolyte fluid comprises an additive, the additive designed to react with ambient air outside of the electrolyte loop to patch a leak of the first electrolyte fluid.

9. The system of claim 1, further comprising:
a sensor to determine a state of a component connected to the electrolyte loop; and
a siphon isolator configured to isolate the component from the electrolyte loop based on the determined state of the component.

10. A method, comprising:
flowing a first electrolyte fluid through an electrolyte loop;
charging, at a charging stack the first electrolyte fluid using electricity from an electrical power source; and
supplying, at a first load stack, electricity to a first load using electrochemical energy from the first electrolyte fluid.

11. The method of claim 10, wherein said supplying, at a first load stack, electricity to a first load comprises:
supplying, at the first load stack, electricity to a direct current (DC) electrical bus, and the DC electrical bus supplies DC electrical power to the first load and a second load.

12. The method of claim 10, further comprising:
determining a state of the first electrolyte fluid; and
causing a pump to adjust a flow rate of the first electrolyte fluid through the first load stack based on the determined state of the first electrolyte fluid.

13. The method of claim 10, further comprising:
determining a state of the first electrolyte fluid; and
pumping second electrolyte fluid from an electrolyte tank into the electrolyte loop based on the measured state of the first electrolyte fluid,
the electrolyte tank storing the second electrolyte fluid at a different state than the state of the first electrolyte fluid.

14. The method of claim 10, wherein the first load comprises at least one of:
a server;
a server rack;
a central processing unit;
a graphics processing unit;
a Tensor processing unit;
a neural processing unit;
a storage cluster;
a network component;
a DC to DC converter;
a DC to alternating current (AC) inverter;
an air handling unit;
an administrative load;
lighting; or
a heating system.

15. The method of claim 10, further comprising:
transferring, at a first heat exchanger, heat generated by the first load to the first electrolyte fluid; and
cooling, at a second heat exchanger, the first electrolyte fluid.

16. The method of claim 10, wherein said flowing a first electrolyte fluid through an electrolyte loop comprises at least one of:
flowing an anolyte fluid through an anolyte loop; or
flowing a catholyte fluid through a catholyte loop.

17. The method of claim 10, further comprising:
adding, to the first electrolyte fluid, an additive designed to react with ambient air outside of the electrolyte loop to patch a leak of the first electrolyte fluid.

18. The method of claim 10, further comprising:
determine a state of a component connected to the electrolyte loop; and
introducing a gas into a siphon isolator to isolate the component from the electrolyte loop based on the determined state of the component.

19. A datacenter, comprising:
a direct current (DC) electrical bus supplying DC electrical power to an electrical load;
a first load stack configured to supply electricity to the DC electrical bus using electrochemical energy from electrolyte fluid flowing through an electrolyte loop; and
a charging stack configured to charge the electrolyte fluid using electricity from an electrical power source.

20. The datacenter of claim 19, further comprising:
a first heat exchanger configured to transfer heat generated by the server component to the electrolyte fluid; and
a second heat exchanger configured to cool the electrolyte fluid.
